(19) United States
(12) Patent Application Publication
(10) Pub. No.: US 2014/0373783 A1
(43) Pub. Date: Dec. 25, 2014

(54) FILM FORMING DEVICE

(71) Applicant: TOKYO ELECTRON LIMITED, Tokyo (JP)

(72) Inventors: Ikuo SAWADA, Kawasaki-shi (JP); Masato MORISHIMA, Tsukuba City (JP); Yukimasa SAITO, Nirasaki City (JP)

(21) Appl. No.: 14/484,598

(22) Filed: Sep. 12, 2014

Related U.S. Application Data
(63) Continuation of application No. PCT/JP2013/000526, filed on Jan. 31, 2013.

(30) Foreign Application Priority Data
Mar. 15, 2012 (JP) 2012-058852
Aug. 13, 2012 (JP) 2012-179386

(51) Int. Cl. C23C 16/513

(52) U.S. Cl. CPC C23C 16/513
USPC 118/723 R

(57) ABSTRACT

A film forming device forms a thin film on a substrate by reacting reaction gases in a process vessel. Electrode portions each oriented vertically are arranged to be spaced from each other in a horizontal direction. By applying high-frequency powers having different phases to adjacent electrode portions, a strong plasma generation space is formed above the substrate placed on a mounting table, while a weak plasma generation space is formed in the gap between the electrode portions and the substrate. A first reaction gas is supplied to the strong plasma generation space and a second reaction gas that forms the thin film by reacting with the active species of the first reaction gas is supplied to the weak plasma generation space. The reaction gases in the weak plasma generation space are discharged through exhaust channels.

### CROSS-REFERENCE TO RELATED APPLICATIONS

This application is a Continuation Application of PCT International Application No. PCT/JP2013/000526, filed Jan. 31, 2013, which claimed the benefit of Japanese Patent Application Nos. 2012-058852 and 2012-179386, filed on Mar. 15, 2012 and Aug. 13, 2012, the entire content of each of which is hereby incorporated by reference.

### TECHNICAL FIELD

The present disclosure relates to a technique for forming a thin film of silicon or the like on a large-area substrate used in a solar cell or the like or a semiconductor wafer used in manufacturing a semiconductor device.

### BACKGROUND

Recently, extensive studies have been conducted on thin film silicon solar cells which can consume a small amount of silicon and relatively easily be formed in a large area compared to bulk type crystalline silicon solar cells. For example, tandem thin-film silicon solar cells (hereinafter, simply referred to as solar cells) are configured to enhance light energy conversion efficiency by laminating an amorphous silicon film formed on an upper surface of a microcrystalline silicon film such that each film absorbs light having a different wavelength range.

In a case where an amorphous silicon film (a-Si film) or a microcrystalline silicon film (μc-Si film) is formed on a large-area substrate, for example, a chemical vapor deposition (CVD) method or the like is used such that a monosilane (SiH₄) gas reacts with a hydrogen (H₂) gas in a vacuum atmosphere to deposit silicon on the substrate. The a-Si film and μc-Si film may be selectively formed by adjusting a partial pressure ratio between SiH₄ gas and H₂ gas.

The applicant had previously developed a film forming device using a plasma CVD method in which high frequency power, microwave or the like is applied to convert SiH₄ or H₂ into plasma and generated active species which may react with each other to form a μc-Si film or the like on a large-area substrate such as a glass substrate.

In a development process of such a film forming device, there is a need to develop a technique of making a film thickness uniform in a plane of a large-area substrate, or also, a technique of reducing defects of an Si film formed by introducing active species having dangling bonds into the film or by introducing high order silanes grown in a particulate state. In addition, it is also required to form an Si film having few defects and high in-plane uniformity on a semiconductor wafer (hereinafter, referred to as a wafer) used in manufacturing a semiconductor device.

### SUMMARY

The present disclosure provides some embodiments of a film forming device capable of forming a thin film having a good film quality and uniform film thickness.

According to one embodiment of the present disclosure, there is provided a film forming device of forming a thin film on a substrate by reacting a plurality of reaction gases in a process vessel, the film forming device including: a mounting table installed in the process vessel to be mounted with the substrate; a plurality of plate-shaped electrode portions disposed, over the substrate mounted on the mounting table, to be spaced apart from each other in a transverse direction with each of the electrode portions vertically oriented, so that strong plasma generation spaces are defined between the electrode portions, the electrode portions being configured to define a weak plasma generation space in a gap between lower ends of the electrode portions and the substrate, the weak plasma generation space being configured to generate plasma having a weaker emission intensity than plasma generated in the strong plasma generation spaces; a first reaction gas supply unit configured to supply a first reaction gas into the strong plasma generation spaces; a second reaction gas supply unit configured to supply a second reaction gas into regions under the strong plasma generation spaces or into the weak plasma generation space, the second reaction gas reacting with active species of the first reaction gas to form the thin film on the substrate; an exhaust unit configured to exhaust the reaction gases from the weak plasma generation space; and a first and second high frequency power source part configured to respectively apply high frequency powers having different phases to one side set and the other side set of the electrode portions which are adjacent with the strong plasma generation spaces interposed therebetween, wherein a distance between the adjacent electrode portions with the strong plasma generation spaces interposed therebetween is in a range of 2 mm or more to 20 mm or less, and a distance between the substrate on the mounting table and the electrode portions is in a range of 5 mm or more to 100 mm or less.

According to another embodiment of the present disclosure, there is provided a film forming device of forming a thin film on a substrate by reacting a plurality of reaction gases in a process vessel, the device including: a mounting table installed in the process vessel to be mounted with the substrate; a plate-shape first electrode portion configured to cover an upper side of a plane surface of the substrate, a plurality of openings being formed in the first electrode portion to be spaced apart from each other; a plurality of second electrode portions respectively disposed inside the openings with gaps formed between inside surfaces of the openings and the second electrode portions so that strong plasma generation spaces are defined by the gaps, the first and second electrode portions being configured to define a weak plasma generation space in a gap between lower ends of the first and second electrode portions and the substrate, the weak plasma generation space being configured to generate plasma having a weaker emission intensity than plasma generated in the strong plasma generation spaces; a first reaction gas supply unit configured to supply a first reaction gas into the strong plasma generation spaces; a second reaction gas supply unit configured to supply a second reaction gas into regions under the strong plasma generation spaces or into the weak plasma generation space, the second reaction gas reacting with active species of the first reaction gas to form the thin film on the substrate; an exhaust unit configured to exhaust the reaction gases from the weak plasma generation space; and first and second high frequency power source parts configured to respectively apply high frequency powers having different phases to the first and second electrode portions, wherein the gaps defining the strong plasma generation spaces are in a range of 2 mm or more to 20 mm or less, and the gap defining the weak plasma generation space is in a range of 5 mm or more to 100 mm or less.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal side sectional view of a film forming device according to an embodiment of the present disclosure.

FIG. 2 is a perspective view showing a configuration of an external appearance of the film forming device.

FIG. 3 is a partially cutaway perspective view illustrating a configuration of electrode portions installed in the film forming device.

FIG. 4 is a bottom view of the electrode portions.

FIG. 5 is a view illustrating a configuration of a power supply system configured to supply high frequency powers to the electrode portions.

FIG. 6 is a view illustrating the operation of the film forming device.

FIG. 7 is a view illustrating a film forming device according to a second embodiment.

FIG. 8 is a first view illustrating a film forming device according to a third embodiment.

FIG. 9 is a second view illustrating the film forming device according to the third embodiment.

FIG. 10 is a bottom view showing a configuration of electrode portions of a film forming device according to a fourth embodiment.

FIG. 11 is a bottom view showing a configuration of electrode portions of a film forming device according to a fifth embodiment.

FIG. 12 is a bottom view showing an arrangement of electrode portions of a film forming device according to a sixth embodiment.

FIG. 13 is an enlarged view of a bottom surface of the electrode portions according to the sixth embodiment.

FIG. 14 is a partially cutaway perspective view of the electrode portions according to the sixth embodiment.

FIG. 15 is a view illustrating a power supply system of the film forming device according to the sixth embodiment.

FIG. 16 is a bottom view showing a modification of the electrode portions according to the sixth embodiment.

FIG. 17 is a bottom view showing a second modification of the electrode portions according to the sixth embodiment.

FIG. 18 is a (first) bottom view showing a third modification of the electrode portions according to the sixth embodiment.

FIG. 19 is a (second) bottom view showing the third modification of the electrode portions according to the sixth embodiment.

FIG. 20 is a bottom view showing a configuration of the electrode portions when a wafer is rotated.

FIGS. 21A and 21B show views illustrating discharge states in the film forming devices according to Example and Comparative Example.

FIG. 22 is a diagram illustrating a film forming rate distribution of the film forming device.

FIGS. 23A and 23B show views illustrating experimental results of an electron density distribution of the film forming devices according to Examples.

FIGS. 24A to 24C show waveform diagrams of high frequency powers supplied to the film forming device according to Examples.

FIG. 25 is a diagram illustrating relationships between internal pressure of a process vessel and intensity of an electric field formed on a substrate.

FIG. 26 is a diagram illustrating relationships between a flow rate ratio of reaction gases and a degree of crystallization.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

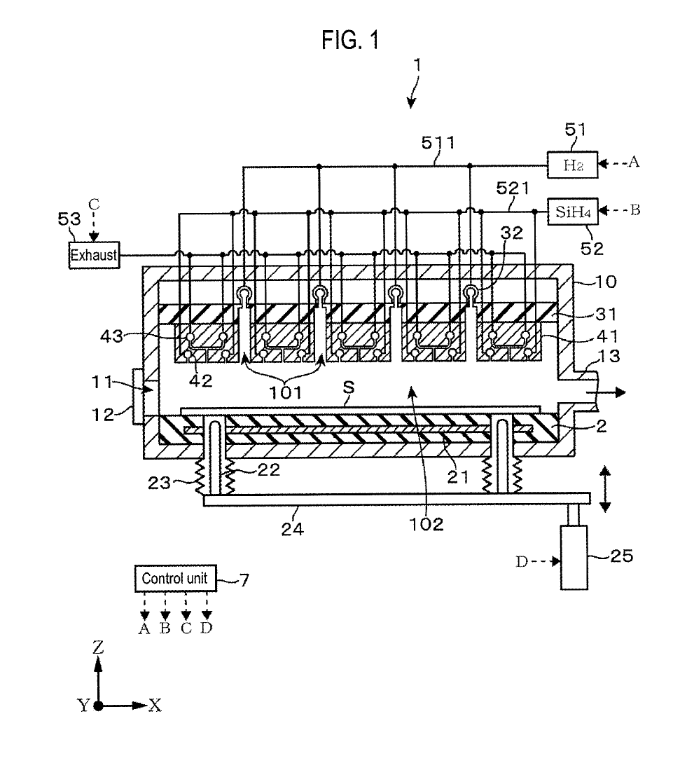

As an embodiment of the present disclosure, a film forming device, in which a μc-Si film as a thin film is formed by generating capacitively coupled plasma between electrode portions disposed adjacent to each other and activating H₂ (a first reaction gas) to react with SH₄ (a second reaction gas), will be described with reference to FIGS. 1 to 5.

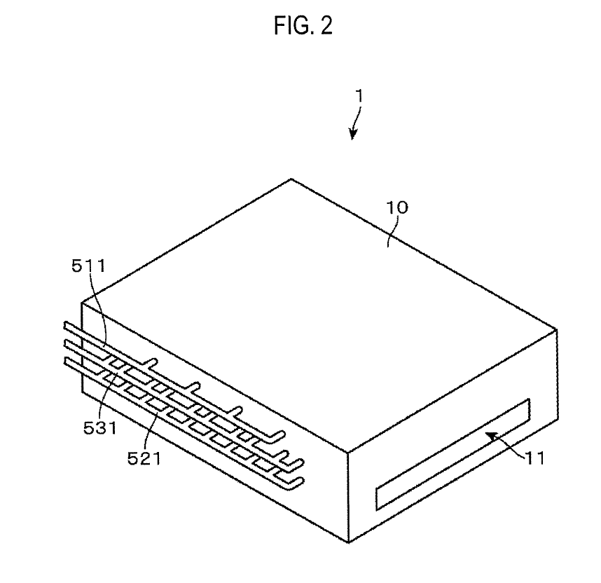

As shown in FIG. 1, a film forming device 1 is configured such that a mounting table 2 to be mounted with a substrate S, on which a film will be formed, and electrode portions 41, which defines not only strong plasma generation spaces 101 for supplying active species of H₂ on a surface of the substrate S mounted on the mounting table 2 but also a weak plasma generation space 102 for reacting the active species with SiH₄, are arranged inside a process vessel 10 that is a vacuum vessel. As shown in FIGS. 1 and 2, the process vessel 10 is configured as a flat sealable vessel made of metal, for example. A size of the process vessel 10 may be large enough to accommodate a large-sized glass substrate S of 1100 mm×1400 mm or more.

In the figure, reference numeral 11 designates a loading/unloading port installed in the process vessel 10 to allow for a short side of the substrate S to pass through, and reference numeral 12 designates a gate valve for opening and closing the loading/unloading port 11. In addition, an exhaust pipe 13 configured to vacuum exhaust an interior of the process vessel 10 is installed in a sidewall surface of the process vessel 10, and the internal space of the process vessel 10 may be adjusted, for example, to a pressure of 100 Pa to 2000 Pa, by operating a vacuum pump (not shown) installed at a downstream side of the exhaust pipe 13. Hereinafter, description will be made with a short side direction of the substrate S installed in the process vessel 10 defined as a vertical direction and a long side direction of the substrate S defined as a transverse direction.

The mounting table 2 made of dielectric or the like is disposed on the floor surface of the process vessel 10, and the above described substrate S is mounted on the mounting table 2 to form a μc-Si film thereon. The delivery of the substrate S between the mounting table 2 and an external substrate transfer mechanism (not shown) configured to load and unload the substrate S is performed using lift pins 22 configured to be lifted via a lift plate 24 by a lifting mechanism 25. In FIG. 1, reference numeral 23 designates bellows installed to respectively surround the lift pins 22 in order to maintain the process vessel 10 in a vacuum atmosphere.

A temperature adjuster 21, for example, consisting of a resistance heating element, is embedded in the mounting table 2, and the temperature adjuster 21 may adjust temperature of the substrate S, for example, to 200 degrees C. to 300 degrees C., by supplying heat generated by electric power supplied from a power supply (not shown) to the substrate S via the upper surface of the mounting table 2. Here, the temperature adjuster 21 is not limited to the heating of the substrate S and may include, for example, a Peltier element or the like, for adjusting the temperature of the substrate S to a predetermined level by cooling the substrate S according to process conditions.

The film forming device 1 according to the embodiment is configured to enable the functions listed below to be obtained in order to supply active species such as SiH₃ needed for growth of a μc-Si film at a high concentration to a region in the vicinity of the surface of the substrate S while a substance causing deterioration of the film quality of the sic-Si film, such as active species including Si, SiH, or SiH₂ other than SiH₃, high order silanes, or their particulates, is prevented from being supplied to the substrate S.

(1) The strong plasma generation spaces 101 are configured as the spaces into which H₂ (the first reaction gas) is supplied, thereby obtaining H radicals as active species. In the meantime, the weak plasma generation space 102 in which plasma having weaker emission intensity than plasma generated in the strong plasma generation spaces 101 is configured as the space over the upper surface of the substrate S in which the H radicals react with SiH₄ (the second reaction gas), thereby supplying SiH₃ to the surface of the substrate S at a high concentration while suppressing the generation of unnecessary active species.

(2) By rapidly exhausting a mixed gas of the H radicals and SiH₄ from the surface of the substrate S, the generation of unnecessary active species from unnecessary radical reaction of the H radicals and SiH₄ is suppressed.

Hereinafter, the configuration of the electrode portions 41 and the like installed in the film forming device 1 in order to obtain the above-described functions will be described.

As shown in FIGS. 1, 3 and 6, the plate-shaped electrode portions 41, which are disposed, over the substrate S mounted on the mounting table 2, to be spaced apart from each other in the transverse direction to divide the space within the process vessel 10, are disposed in the film forming device 1. Each of the electrode portions 41 consists of, for example, a narrow and long plate-shaped metal member, and is disposed to extend from a ceiling portion (an insulating member 31 described later) of the process vessel 10 toward a lower side with the electrode portion vertically oriented. In addition, the electrode portion 41 is formed such that its length in the vertical direction is larger than that of the short side of the substrate S.

The respective electrode portions 41 are equidistantly disposed in the long side direction of the substrate S (in the transverse direction), and accordingly, a narrow and long space (the strong plasma generation space 101) extending in the short side direction of the substrate S (in the vertical direction) is defined between adjacent two of the electrode portions 41. The respective electrode portions 41 are fixed to the ceiling portion of the process vessel 10 via the insulating member 31 and supplied with high frequency power from first and second power source parts 61 and 62, thereby generating plasma in the strong plasma generation spaces 101. The power supply system will be described in detail later.

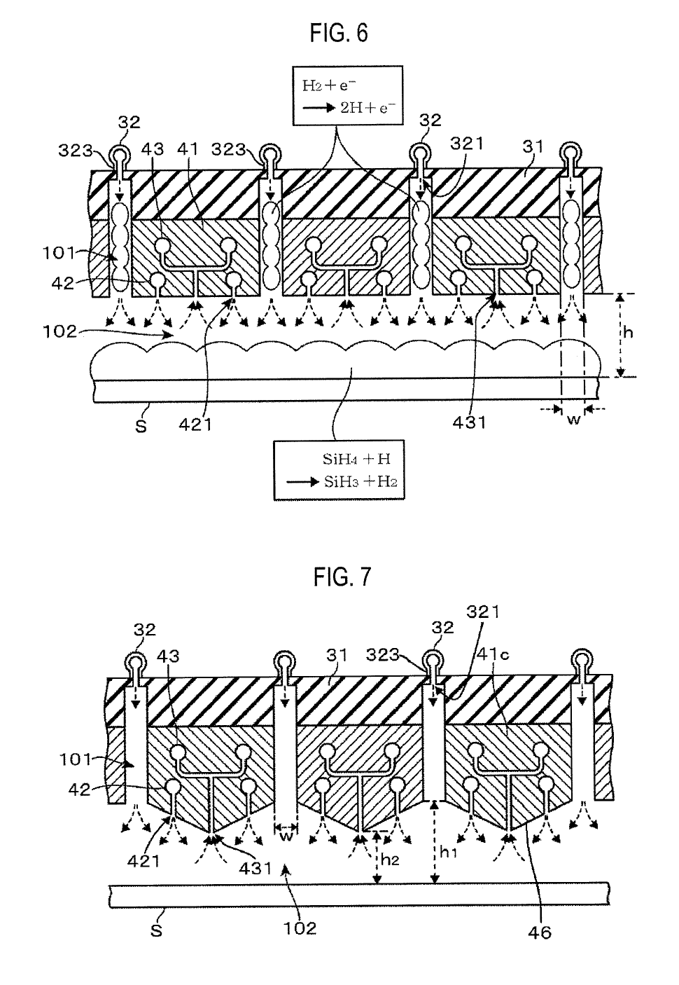

As shown in FIG. 6, a distance w between the electrode portions 41 disposed adjacent to each other with the strong plasma generation spaces 101 interposed therebetween is adjusted to fall within a range of, for example, 2 mm or more to 20 mm or less, or more preferably, 4 mm or more to 10 mm or less. If the distance between the electrode portions 41 is smaller than 2 mm, no plasma is generated in the strong plasma generation spaces 101, while if the distance is larger than 20 mm, the plasma generated in the process vessel 10 becomes weak, which then will decrease the production amount of the H radicals and thus deteriorate a film forming rate.

Further, in the electrode portions 41, a distance h between the bottom surface of the electrode portions 41 and the surface of the substrate S is adjusted to fall within a range of 5 mm or more to 100 mm or less, or more preferably, 7 mm or more to 30 mm or less. If the distance between the electrode portions 41 and the substrate S is larger than 100 mm, the plasma generated in the weak plasma generation space 102 becomes weak, which may deteriorate a film forming rate. In addition, if the distance between the electrode portions 41 and the substrate S is smaller than 5 mm, an intensity of the plasma generated in the weak plasma generation space 102 becomes similar to that of the plasma generated in the strong plasma generation spaces 101, so that SiH₄ are excessively decomposed, which becomes a factor in deteriorating the film quality of the μc-Si film.

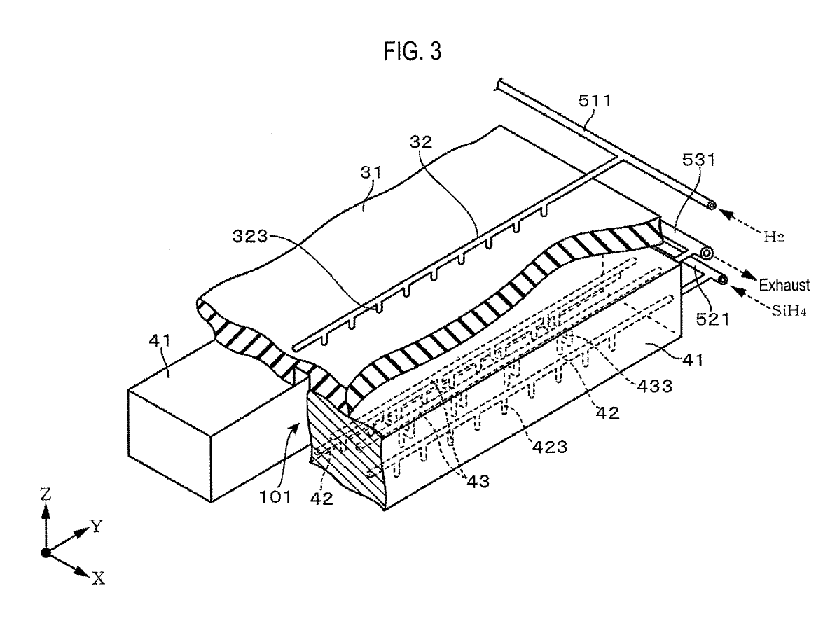

Sequentially, a mechanism of supplying reaction gases to the strong plasma generation spaces 101 or the weak plasma generation space 102 and exhausting gases after the reaction will be described. As shown in FIGS. 1 and 3, a space is defined between the upper surface of the insulating member 31 having the electrode portions 41 fixed thereto and the process vessel 10, and H₂ supply channels 32 configured to supply H₂ to the strong plasma generation spaces 101 are disposed in this space.

The H₂ supply channels 32 are disposed on the upper sides of the strong plasma generation spaces 101, respectively, and as shown in FIGS. 3, 4 and 6, H₂ may be supplied to the strong plasma generation spaces 101 through branching channels 323, which are connected to the H₂ supply channels 32 along the direction in which the electrode portions 41 extend, and H₂ supply holes 321 formed in the insulating member 31.

As shown in FIGS. 1 to 3, the plurality of H₂ supply channels 32 may be connected to a common H₂ supply line 511, receive hydrogen from an H₂ supply unit 51 consisting of an H₂ tank, a flow rate adjusting valve and the like, and supply a predetermined amount of H₂ to the respective strong plasma generation spaces 101. The H₂ supply channels 32, the H₂ supply line 511, the H₂ supply unit 51 and the like correspond to a first reaction gas supply unit in this embodiment.

In addition, as shown in FIGS. 1 and 3, SiH₄ supply channels 42 configured to supply SiH₄ to the weak plasma generation space 102 and exhaust channels 43 configured to exhaust the reaction gases supplied to the weak plasma generation space 102 are formed inside the respective electrode portions 41.

The SiH₄ supply channels 42 in this embodiment are respectively formed (in a pair) in regions close to both sidewall surfaces of the lower side of each electrode portion 41 along the direction in which the electrode portion 41 extends, as shown by broken lines in FIG. 3.

A plurality of branching channels 423 may extend downwards from the respective SiH₄ supply channels 42 while being spaced apart from each other, thereby supplying SiH₄ toward the weak plasma generation space 102 through SiH₄ supply holes 421 formed at the bottom surface of each electrode portion 41 and arranged in two lines along both the sidewall surfaces of the electrode portion 41 in the fore and aft direction, as shown in FIGS. 3, 4 and 6. Here, the SiH₄ supply holes 421 are not limited to the case in which they are formed at the bottom surfaces of the electrode portions 41. For example, the branching channels 423 may horizontally extend from the SiH₄ supply channels 42 and the SiH₄ supply holes 421 may be formed in the sidewall surfaces of the lower side of each electrode portion 41, thereby supplying SiH₄ to the lower sides of the strong plasma generation spaces 101.

As shown in FIGS. 1 to 3, the SiH₄ supply channels 42 formed inside the respective electrode portions 41 may be connected to a common SiH₄ supply line 521, receive SiH₄ from an SiH₄ supply unit 52 consisting of an SiH₄ tank, a flow rate adjusting valve and the like, and supply a predetermined amount of SiH₄. The SiH₄ supply channels 42, the SiH₄ supply line 521, the SiH₄ supply unit 52 and the like correspond to a second reaction gas supply unit in this embodiment.

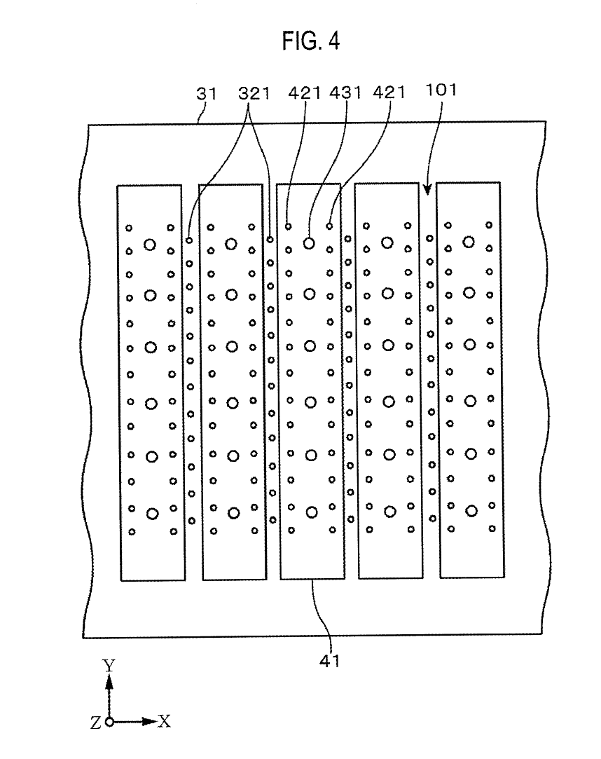

Further, two of the exhaust channels 43 are formed in a region above and between the above-described SiH₄ supply channels 42 inside each electrode portion 41, along the direction in which the electrode portion 41 extends and in parallel with the SiH₄ supply channels 42. Also, a plurality of branching channels 433 extend downwards from the two exhaust channels 43, are joined to each other in the middle thereof in pairs, and are connected to exhaust holes 431 formed at the bottom surface of the electrode portion 41. As shown in FIG. 4, the exhaust holes 431 are disposed in a line in a central portion of the bottom surface of the electrode portion 41 so as to be interposed between the two lines of the SiH₄ supply holes 421.

As shown in FIGS. 1 to 3, the exhaust channels 43 formed inside each electrode portion 41 may be connected to an external exhaust part 53 consisting of a vacuum pump and the like via a common exhaust line 531, thereby exhausting the reaction gases in the weak plasma generation space 102 to the outside. The exhaust channels 43, the exhaust line 531, the exhaust part 53 and the like correspond to an exhaust unit in this embodiment.

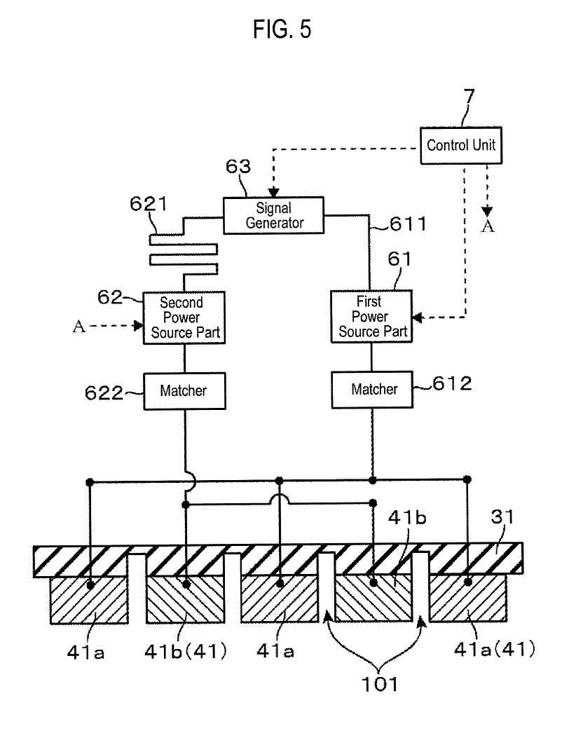

Sequentially, the power supply system configured to supply high frequency power to the electrode portions 41 in the process vessel 10 will be described. As shown in FIG. 5, among two sets of the electrode portions 41 with one of the strong plasma generation spaces 101 interposed therebetween, one side set of the electrode portions 41 (represented as electrode portions 41 a in FIG. 5) is connected to the first power source part 61 (first high frequency power source part) configured to apply a high frequency power of, for example, 13.56 MHz and 2500 W (per one electrode portion), to the respective electrode portions 41a. Meanwhile, among two sets of the electrode portions 41 with one of the strong plasma generation spaces 101 interposed therebetween, the other side set of the electrode portions 41 (represented as electrode portions 41b in FIG. 5) is connected to the second power source part 62 (second high frequency power source part) configured to apply a high frequency power of, for example, 13.56 MHz and 2500 W, the phase of which is delayed 180 degrees (inverted) with respect to the high frequency power supplied from the first power source part 61. In the figure, reference numerals 612 and 622 designate matchers that match the high frequency powers respectively supplied from the power source parts 61 and 62.

According to the example shown in FIG. 5, each of the first and second power source parts 61 and 62 is configured as an external synchronization power source capable of outputting high frequency power synchronized with an externally input frequency signal. In addition, when the first and second power source parts 61 and 62 are connected to a common frequency signal generator 63, a second signal line 621 connecting the second power source part 62 and the frequency signal generator 63 is formed longer than a first signal line 611 connecting the first power source part 61 and the frequency signal generator 63.

Accordingly, a frequency signal output from the frequency signal generator 63 is input to the second power source part 62 at a point of time more delayed than a point of time at which the frequency signal is input to the first power source part 61. The delay is used to adjust the phases of the high frequency powers. It was experimentally confirmed as shown in Examples described later that the phases of the high frequency powers respectively output from the power source parts 61 and 62 could be adjusted according to this method.

However, a method of adjusting a phase difference between the first power source part 61 and the second power source part 62 is not limited to a specific method, and other methods may be employed. For example, a forced balun circuit is connected to the output of one of the high frequency power source parts, one output of the forced balun circuit is applied to the electrode portions 41a and the other output, the phase of which is inverted with respect to the one output, is applied to the electrode portions 41b.

The high frequency powers having phases inverted with respect to each other are applied to the adjacent electrode portions 41(41a and 41b) with the strong plasma generation spaces 101 interposed therebetween, thereby forming the strong plasma generation spaces 101, in which H₂ supplied to gaps between the electrode portions 41 is converted into plasma to generate H radicals. In addition, plasma caused by the high frequency powers applied to the electrode portions 41 is also generated between the respective electrode portions 41 and the substrate S mounted therebelow.

Here, contrary to the strong plasma generation spaces 101 in which the high frequency powers, the phases of which are inverted with respect to each other to be in a so-called push-pull state, are applied to the electrode portions 41a and 41b, the substrate S mounted on the mounting table 2 is in an electrically floating state. Accordingly, plasma weaker than the plasma generated in the strong plasma generation spaces 101 is generated in the space between the respective electrode portions 41 and the substrate S (the weak plasma generation space 102).

Here, a relative intensity ratio between the plasma generated in the strong plasma generation spaces 101 and the plasma generated in the weak plasma generation space 102, for example, an electron temperature ratio or an electron density ratio of the plasmas may be determined by an emission intensity ratio when the interior of the process vessel 10 is photographed by a CCD camera with a band-pass filter. When a ratio of an emission intensity of the weak plasma generation space 102 to an emission intensity of the strong plasma generation spaces 101 is less than 1, it may be said that plasma weaker than the plasma generated in the strong plasma generation spaces 101 is generated in the weak plasma generation space 102.

The film forming device 1 having the above-described configuration is connected to a control unit 7, as shown in FIGS. 1 and 5. The control unit 7 is configured, for example, as a computer including a CPU and a memory part (both not shown), and the memory part stores a program consisting of a step (command) group for controlling the operations of the film forming device 1, i.e., the operations of loading the substrate S into the process vessel 10, forming the μc-Si film having a predetermined film thickness on the substrate S mounted on the mounting table 2, and unloading the substrate S. The program is stored, for example, in a storage medium, such as a hard disc, a compact disc, a magneto-optical disc, or a memory card, and installed to the computer therefrom.

The operation of the film forming device 1 having the above-described configuration will be described. First, when the substrate S is transferred to the film forming device 1 by an external substrate transfer mechanism, the film forming device 1 opens the gate valve 12 of the loading/unloading port 11 and allows the lift pins 22 to protrude from the mounting table 2, then receiving the substrate S from the substrate transfer mechanism.

After the delivery of the substrate S is completed, the substrate transfer mechanism is kept out of the process vessel 10, the gate valve 12 is closed, and the lift pins 22 are lowered to mount the substrate S on the mounting table 2. In addition, in parallel with these operations, an internal pressure of the process vessel 10 is adjusted to fall within a range of 100 Pa to 2000 Pa, for example, to 900 Pa, by vacuum exhausting the interior of the process vessel 10, and a temperature of the substrate S is adjusted to be, for example, 250 degrees C., by the temperature adjuster 21.

After the adjustment of the internal pressure of the process vessel 10 and the adjustment of the temperature of the substrate S are completed, 40000 sccm, for example, of the total amount of H₂ is supplied to the strong plasma generation spaces 101 from the H₂ supply unit 51 through the H₂ supply line 511 and the H₂ supply channels 32, and H₂ is converted into plasma by respectively applying the high frequency powers from the first and second power source parts 61 and 62 to the electrode portions 41. In the meantime, 400 sccm, for example, of the total amount of SiH₄ is supplied to the weak plasma generation space 102 from the SiH₄ supply unit 52 through the SiH₄ supply line 521 and the SiH₄ supply channels 42.

As a result, as schematically shown in FIG. 6, downflows of H₂ supplied from the H₂ supply channels 32 which flows downward are formed in the strong plasma generation spaces 101. The H₂ collides with electrons supplied from the electrode portions 41 to be converted into plasma and active species are generated. Since H₂ is a molecule only consisting of two hydrogen atoms, only hydrogen radicals are generated as the active species from the hydrogen plasma as shown in following Formula (1):

H₂+e⁻→2 H+e⁻ (1)

In the meantime, SiH₄ flowing out of the SiH₄ supply holes 421 is supplied into the weak plasma generation space 102 between the electrode portions 41 and the substrate S, is mixed with the H radicals fed from the upstream side, and spreads over the surface of the substrate S. As a result, the mixed gas of the H radicals and SiH₄ is supplied onto the surface of the substrate S, and the reaction represented by following Formula (2) proceeds in this mixed gas:

SiH₄+H→SiH₃+H₂ (2)

By doing so, SiH₃ is supplied to the surface of the substrate S at a high concentration, thereby forming a good quality μc-Si film on the surface of the substrate S from SiH₃.

At this time, by generating the plasma weaker than the plasma generated in the strong plasma generation spaces 101 in the weak plasma generation space 102, as shown in experimental results described later, while maintaining conditions where unnecessary active species such as Si, SiH and SiH₂ are hardly generated as compared with a conventional capacitively coupled type film forming device using parallel plates, the reaction represented by Formula (2) may proceed, and ion damages to the substrate S may also be reduced.

In addition, for example, if any one side set of the electrode portions 41a and 41b, for example, the electrode portions 41b, are grounded and plasma is generated in the strong plasma generation spaces 101, plasma is hardly generated in the spaces between the grounded electrode portions 41b and the substrate S, and relatively strong plasma is generated in the spaces between the electrode portions 41a and the substrate S. Accordingly, the regions in which plasma is generated and the regions in which no plasma is generated are formed in the weak plasma generation space 102, and thus, good in-plane uniformity may not be obtained in the μc-Si film formed on the substrate S in some cases.

Contrarily, when high frequency powers having phases inverted with respect to each other are applied to both the adjacent electrode portions 41a and 41b, weak plasma is easily uniformly generated in any space between the electrode portions 41 and the substrate S, thereby enabling the μc-Si film having high in-plane uniformity to be obtained.

Further, SiH₃ generated in the mixed gas according to Formula (2) further reacts with the H radicals as the time passes by, and sequentially generates SiH₂, SiH, and Si. Thus, these active species, or high order silanes or particulates that are polymers of the active species are introduced into the μc-Si film, thereby reducing the film quality.

Therefore, in the film forming device 1 according to the embodiment, the exhaust holes 431 configured to exhaust the reaction gases in the weak plasma generation space 102 are formed in the bottom surfaces of the respective electrode portions 41. In addition, since the interior of the process vessel 10 is always vacuum exhausted toward the exhaust channels 43 through the exhaust holes 431, after reaching the surface of the substrate S, the mixed gas spreading in the weak plasma generation space 102 changes its flow direction upward and is rapidly exhausted from the process vessel 10 through the exhaust holes 431.

By forming the exhaust holes 431 in the bottom surfaces of the electrode portions 41 as described above to reduce a residence time of the mixed gas on the substrate S, even when the reaction of the H radicals and SiH₄ proceeds in the weak plasma generation space 102, the generation of any unnecessary active species can be suppressed while SiH₃ is supplied to the surface of the substrate S at a high concentration, thereby enabling the μc-Si film having a good film quality to be obtained.

With the above-described configuration, (1) while the strong plasma generation spaces 101 are configured as the space supplied with H₂ to obtain a large amount of H radicals as active species, the weak plasma generation space 102 is configured as the space supplied with SiH₄ to uniformly generate weak plasma over the upper surface of the substrate S on which the film is formed, thereby enabling ion damages to the substrate S to be suppressed and SiH₃ to be supplied to the surface of the substrate S at a high concentration. In addition, (2) by rapidly exhausting the mixed gas of the H radicals and SiH₄ from the substrate S, it is possible to suppress the generation of any unnecessary active species involved by unnecessary radical reaction of the H radicals and SiH₄.

If the μc-Si film having a desired film thickness by performing such film formation on the surface of the substrate S for a predetermined time, the supply of H₂ and SiH₄ and the application of the high frequency powers are stopped, the substrate S is unloaded from the process vessel 10 by the external substrate transfer mechanism by performing an operation in reverse to the loading of the substrate S, and the series of operations are terminated.

According to the film forming device 1 of the embodiment, the following effects are obtained. The high frequency powers the phases of which are different from each other, for example, by 180 degrees, are applied to the one side and other side sets of the plate-shaped electrode portions 41 disposed to be spaced apart from each other, thereby not only generating plasma in the strong plasma generation spaces 101 interposed between the electrode portions 41 but also generating plasma weaker than the plasma generated in the strong plasma generation spaces 101 in the weak plasma generation space 102 in which the film formation is performed. Further, as the H radicals are generated in the strong plasma generation spaces 101 and the reaction of the H radicals and SiH₄ proceeds in the weak plasma generation space 102, it is possible to uniformly form the μc-Si film having few defects on the surface of the substrate S.

As described above, in the film forming device in which the distance w between the adjacent electrode portions 41 is adjusted to fall within a range of 2 to 20 mm and the distance h between the bottom surface of the electrode portions 41 and the surface of the substrate S is adjusted to fall within a range of 5 to 100 mm, methods of forming a μc-Si film having the more uniform film thickness on the substrate S will be listed below.

For example, FIG. 7 shows an example, in which each bottom surface of electrode portions 41c is provided with an inclined surface portion 46, which extends upward as it goes from both sidewall surfaces toward the central portion of the electrode portion 41c, such that a distance h₁ from the substrate S to both the sidewall surfaces of the electrode portion 41c is larger than a distance h₂ from the substrate S to the lower end of the inclined surface portion 46. The sidewall surfaces of the electrode portions 41c correspond to outlets (openings) of the strong plasma generation spaces 101. It was also confirmed from the examples described later that uniform plasma was generated in the vicinity of the outlets.

As the lower end of the inclined surface portion 46 is disposed closer to the substrate S than the outlet of the strong plasma generation space 101, the coupling of the lower end of the inclined surface portion 46 and the substrate S can be relatively intensified, thereby increasing plasma intensity at that location. Therefore, it is possible to reduce the intensity of the plasma generated in the vicinity of the outlets of the strong plasma generation spaces 101 and to improve plasma uniformity in the weak plasma generation space 102. Also, in this embodiment, the distance h₂ is adjusted to fall within a range of 5 to 100 mm.

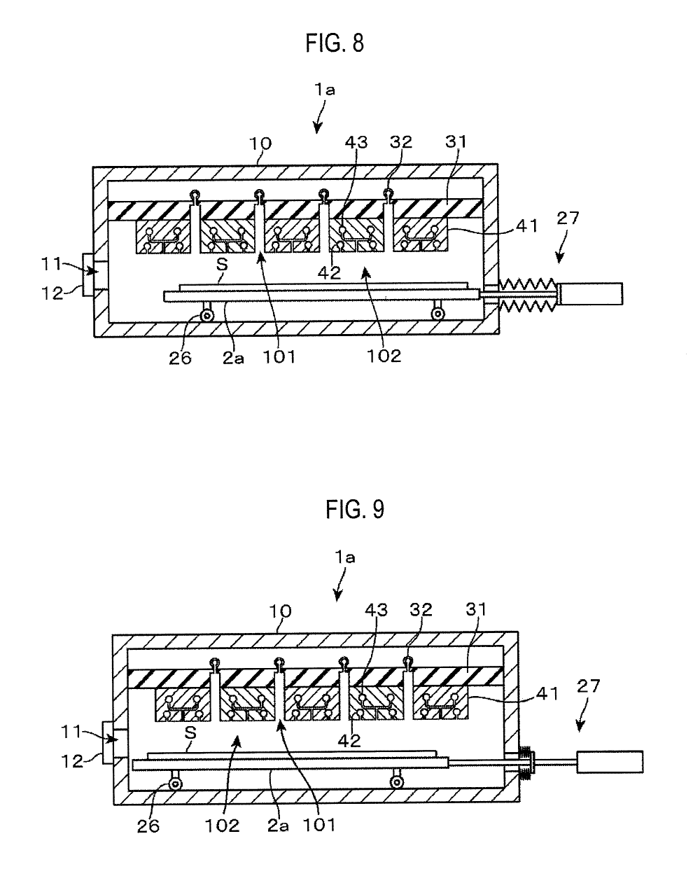

In addition, as shown in FIGS. 8 and 9, a mounting table 2a may be supported on the floor surface of the process vessel 10 via a castor part 26, and the mounting table 2a may be reciprocated along an arrangement direction of the electrode portions 41 by a driving mechanism 27. Even when an electron density in the vicinity of the outlets of the strong plasma generation spaces 101 is high, the thickness of the film formed on the substrate S can be made uniform by moving a region of the substrate S facing the high electron density region according to a reciprocating motion of the substrate S in the transverse direction.

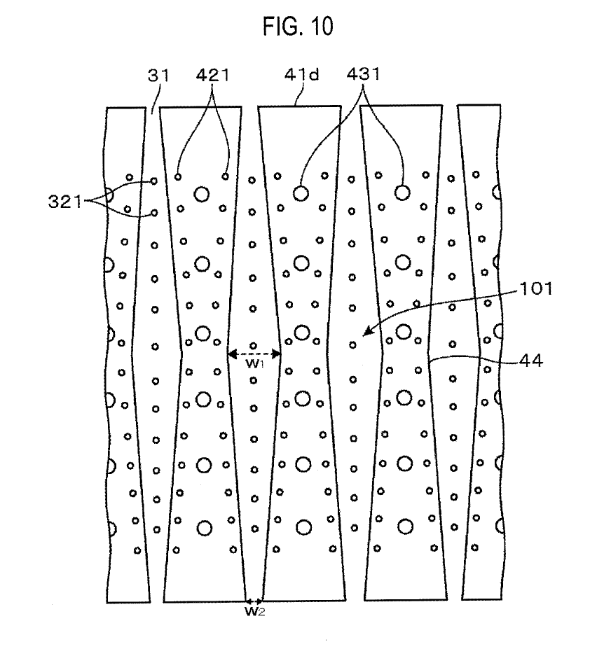

Sequentially, FIG. 10 shows an example of electrode portions 41d, which improve the in-plane uniformity of the film thickness by increasing a distance w between the electrode portions 41 in regions where a film forming rate of the μc-Si film formed on the substrate S is high to reduce the plasma intensity in the strong plasma generation spaces 101 in these regions. For example, a central region of the substrate S in which the SiH₄ supply holes 421 or the exhaust holes 431 are concentrated is supplied with a large amount of H radicals or SiH₄ and tends to have a high film forming rate as compared with lateral end regions of the substrate S, which are close to the inner wall surface of the process vessel 10 and thus have a small number of the SiH₄ supply holes 421 or the exhaust holes 431 as compared with the central region.

Therefore, as shown in the plane view of FIG. 10, concave portions 44 are formed on the sidewall surfaces of the electrode portions 41d such that a distance w₁ between the adjacent electrode portions 41d in the high film forming rate region is increased. As a result, a distance w₂ between the electrode portions 41d in the low film forming rate region becomes relatively small as compared with the high film forming rate region. With this configuration, it is possible to make a film forming rate uniform and promote the improved in-plane uniformity of the film thickness by reducing the plasma intensity in the high film forming rate region.

Here, the plane shape of the electrode portion 41d is not limited to the example illustrated in FIG. 10. For example, the plane shape of the electrode portion 41d may be appropriately modified by specifying the high film forming rate region from a preparatory experiment using the electrode portions 41 shown in FIG. 4 and relatively increasing a distance w between the electrode portions 41d positioned in this region.

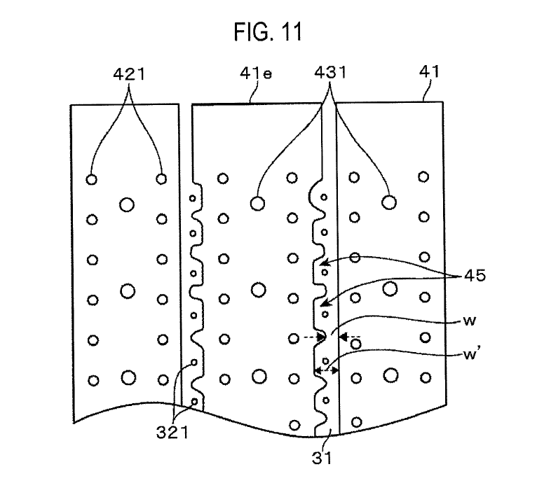

In addition, a method of adjusting a distance between the adjacent electrode portions 41 is not limited to the case in which the distance between the electrode portions 41d is uniformly changed as shown in FIG. 10. For example, as shown in an electrode portion 41e of FIG. 11, cutaway portions 45 may be formed to be spaced apart from each other in the sidewall surfaces of the electrode portion 41e, which has a distance w to the electrode portions 41, such that a distance between the electrode portions 41e and 41 in the cutaway portions 45 is w′. A cutaway depth or an arrangement interval of the cutaway portions 45 may be adjusted such that an average of distances between the electrode portions 41e and 41 throughout the regions in which the cutaway portions 45 are formed and the regions in which the cutaway portions 45 are not formed is w₁ as already described.

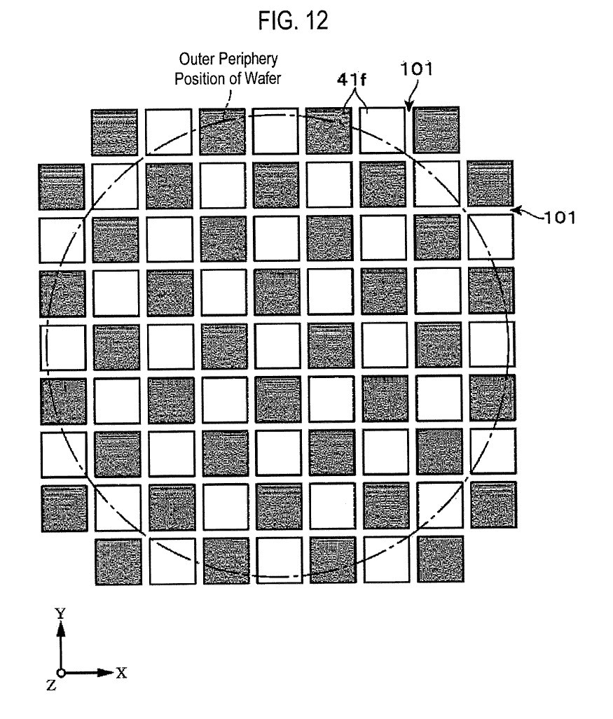

Then, an example of a configuration of a film forming device provided with electrode portions 41f suitable to form a film on a wafer used in manufacturing a semiconductor device will be described with reference to FIGS. 12 to 15. In FIGS. 12 to 15, like reference numerals are used to designate elements having the same functions as the first embodiment shown in FIGS. 1 to 5.

In a process of manufacturing a semiconductor device, a μc-Si film formed on a wafer requires to have a higher level of in-plane uniformity of the film thickness than a film formed on a substrate for a solar cell.

Therefore, the film forming device of this embodiment is different from the film forming device 1 according to the first embodiment, in which the narrow and long plate-shaped electrode portions 41 are disposed to be spaced apart at intervals only in the X-axis direction. For example, in this embodiment, the bottom surface of each electrode portion 41f is shaped, for example, in a square, and these electrode portions 41f are disposed to be spaced apart from each other at intervals not only in the X-axis direction but also in the Y-axis direction as shown in FIG. 12. In other words, the electrode portions 41f of FIG. 12 may be configured by dividing the electrode portions 41 also in the Y-axis direction such that the strong plasma generation spaces 101 are also defined in the intersecting direction (X-axis direction) crossing the direction (Y-axis direction) in which the strong plasma generation spaces 101 shown in FIG. 4 extend.

In the meantime, this embodiment is similar to the first embodiment in that the distance between the electrode portions 41f disposed adjacent to each other with the strong plasma generation spaces 101 interposed therebetween is adjusted to fall within a range of, for example, 2 mm or more to 20 mm or less, or more preferably, 4 mm or more to 10 mm or less, and the distance h between the bottom surface of the electrode portions 41 and the surface of the substrate S is adjusted to fall within a range of 5 mm or more to 100 mm or less, or more preferably, 7 mm or more to 30 mm or less.

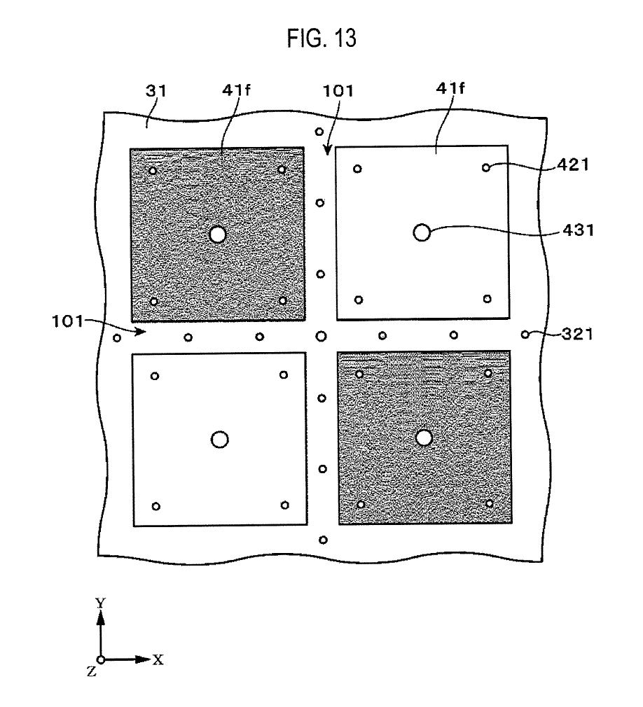

As shown in FIG. 13, the SiH₄ supply holes 421 are formed, for example, at four corner positions in the square bottom surface of each electrode portion 41f, and the exhaust hole 431 is also formed in a central portion surrounded by these SiH₄ supply holes 421. In the meantime, the film forming device of this embodiment is the same as the film forming device 1 of the first embodiment in that the strong plasma generation spaces 101 are formed between the adjacent electrode portions 41f and the H₂ supply holes 321 are formed in the insulating member 31 constituting the ceiling portion of the process vessel 10 in order to supply H₂ to the strong plasma generation spaces 101.

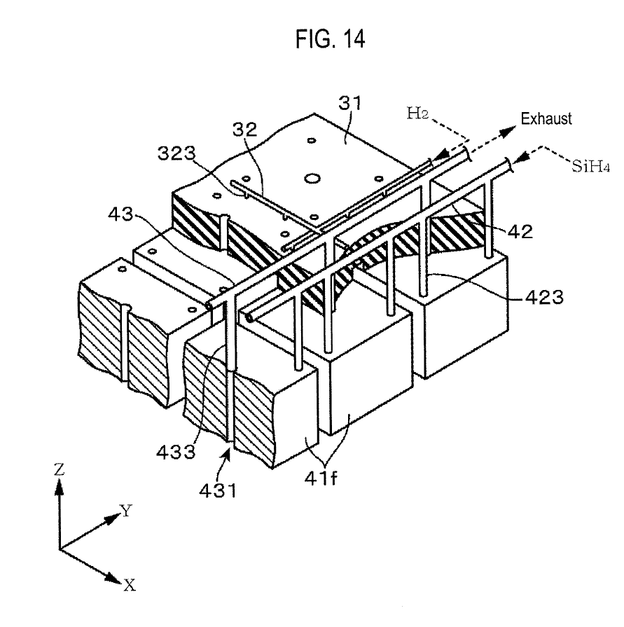

As shown in FIG. 14, SiH₄ gas or H₂ gas is supplied to the SiH₄ supply holes 421 or the H₂ supply holes 321 through the SiH₄ or H₂ supply channel 42 or 32 installed at the upper surface side of the insulating member 31 and the branching channels 423 or 323 penetrating through the insulating member 31 or the electrode portions 41f. In addition, the mixed gas introduced into the exhaust holes 431 is exhausted through the branching channels 433 and the exhaust channels 43. Further, for the purpose of simplification of the drawing, in FIG. 14, the supply and exhaust channels 42, 32 and 43 and the branching channels 423, 323 and 433 are respectively shown only in one set.

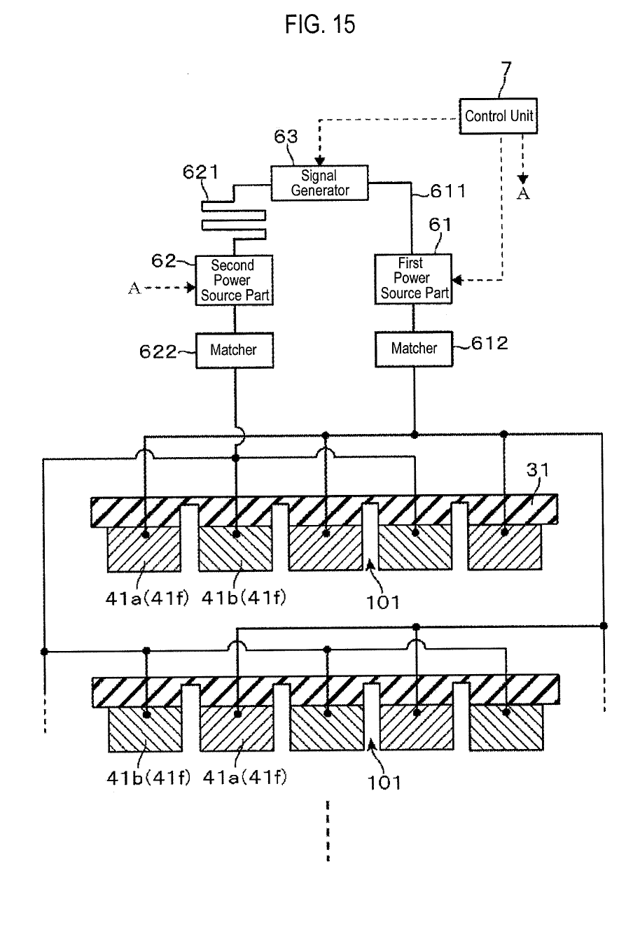

In addition, as schematically shown in FIG. 15, if the electrode portions 41f are respectively connected to the first and second power source parts 61 and 62 so as to apply the high frequency powers the phases of which are inverted with respect to each other to the adjacent electrode portions 41f, as discriminately shown with white and gray in FIG. 12, the electrode portions 41f to which the high frequency powers the phases of which are inverted with respect to each other are respectively applied are arranged checkerwise while being surrounded by the strong plasma generation spaces 101 intersecting and extending in a grid shape. Here, in FIG. 15, reference numeral 41a is assigned to the electrode portions 41f connected to the first power source part 61, and reference numeral 41b is assigned to the electrode portions 41f connected to the second power source part 62, which is similar to FIG. 5.

As the electrode portions 41f are arranged from front to back and side to side with the bottom surface of each electrode portion 41f which is shaped, for example, in a square, and the high frequency powers the phases of which are inverted with respect to each other are applied to the adjacent electrode portions 41f, plasma is dispersed not only in the left and right direction (X-axis direction in FIG. 12) but also the fore and aft direction (Y-axis direction in FIG. 12). Therefore, even though there is a little difference in the film forming rate between respective regions under the electrode portions 41f or the strong plasma generation spaces 101, the regions having different film forming rates are dispersedly disposed. As a result, since small regions having different film thicknesses are dispersedly formed in the entire surface of the wafer, the in-plane uniformity of the film thickness is improved over the entire wafer. Further, in FIG. 12, an outer periphery position of the wafer disposed under the electrode portions 41f is represented by an alternate long and short dash lines.

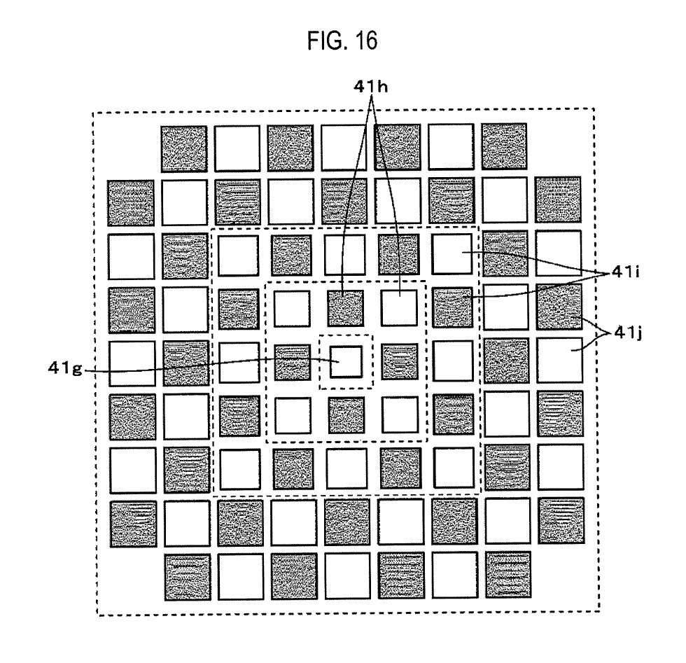

FIG. 16 shows an example configured such that in order to make an arrangement density of electrode portions 41g to 41j small in the central portion of the wafer and large in the peripheral portion thereof, a length of one side of each square bottom surface of the electrode portions 41 g to 41j is gradually increased from the central portion toward the peripheral portion. This example corresponds to the example of the electrode portions 41d shown in FIG. 10. For example, by changing a distance between the adjacent electrode portions 41g to 41j so as to cancel out a difference in arrangement density of the SiH₄ supply holes 421 or the exhaust holes 431, the film forming rate is made uniform to promote the improved in-plane uniformity of the film thickness.

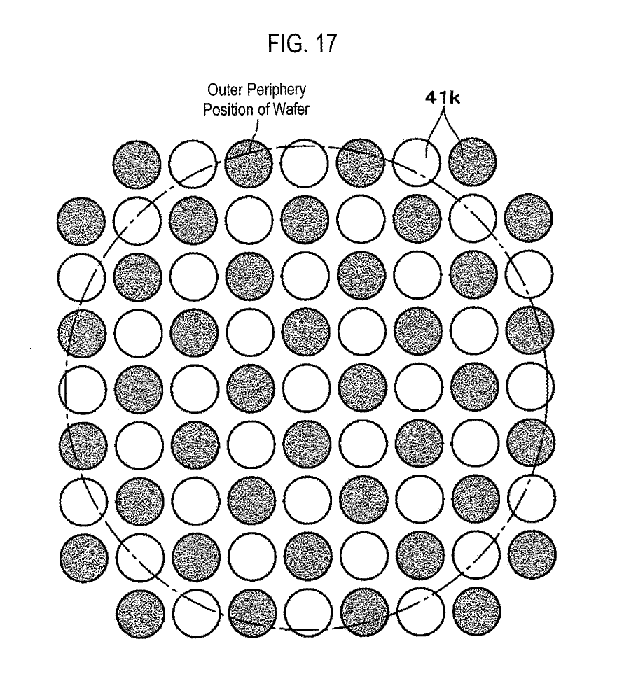

In addition, the shape of the bottom surface of the electrode portion is not limited to a rectangle such as a square, and electrode portions 41k each having a circular bottom surface may be used as shown in FIG. 17, or electrode portions having any other shaped bottom surface may be used. Further, the strong plasma generation spaces 101 are not limited to the case in which they extend perpendicularly across each other in a grid shape, and the strong plasma generation spaces 101 may obliquely cross each other. In this case, the bottom surface of the electrode portion is shaped, for example, in a rhombus.

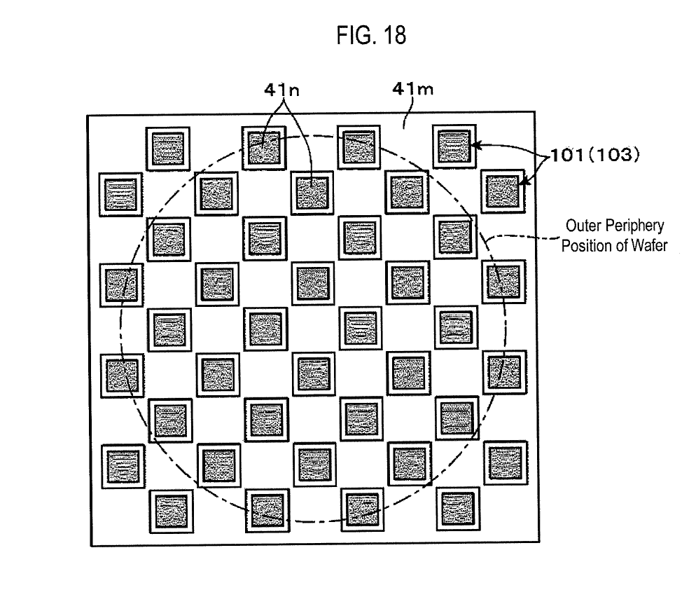

FIG. 18 shows an example in which among electrode portions 41m and 41n, to which high frequency powers the phases of which are inverted with respect to each other are applied, the electrode portion 41m (first electrode portion) is formed into one body. For example, the first electrode portion 41 m is made of a wide metal plate covering the upper plane surface of the wafer, and has openings 103 formed at positions where the electrode portions 41n (second electrode portions) are disposed, wherein the opening 103 is larger than the plane shape of the second electrode portion 41n. Then, the second electrode portions 41n are respectively inserted in the openings 103 so that gaps are defined between the inside surfaces of the openings 103 and the outside surfaces of the second electrode portions 41n disposed in the openings 103, and these gaps serve as the strong plasma generation spaces 101. In the same manner as the electrode portions 41f shown in FIG. 12 already described, the openings 103 of this example are arranged such that the electrode portions 41m and 41n (discriminately shown with white and gray) to which the high frequency powers the phases of which are inverted with respect to each other are respectively applied are arranged checkerwise. As the first electrode portion 41m is formed into one body as in this example, the number of components forming the first electrode portion 41m or the power supply system can be reduced, and thereby reducing cost.

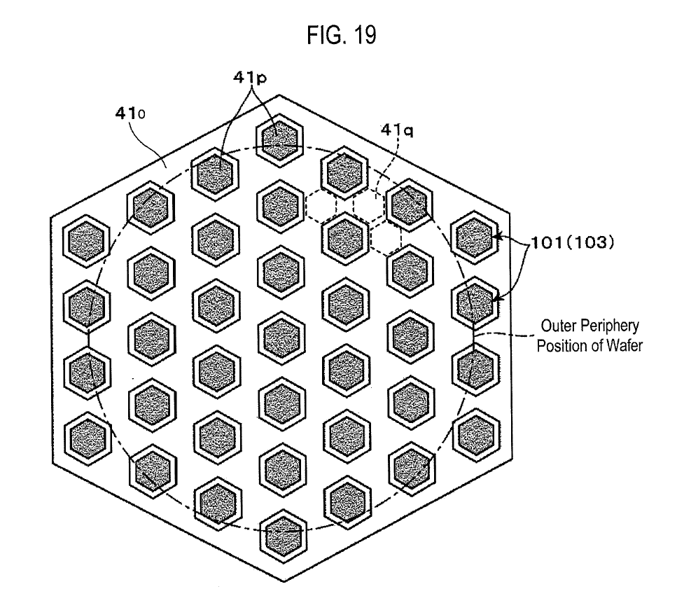

Here, the shape of the integrated first electrode portion 41m or the second electrode portions 41n inserted in the openings 103 is not limited to the example shown in FIG. 18. FIG. 19 shows an example in which hexagonal openings 103 are regularly arranged in a first electrode portion 410 shaped in a hexagon and second electrode portions 41p are respectively inserted in the openings 103. In this example, hexagonal regions 41q (shown by broken lines in FIG. 19) of the first electrode portion 410 interposed between the openings 103, and the second electrode portions 41p are arranged in a honeycomb shape, such that the arrangement of the electrode portions 410 and 41p has high symmetry when viewed from the wafer. As a result, the symmetry of reaction gas flow or plasma distribution may be improved to uniformly form a film. In addition, the second electrode portion may be shaped in a circle as shown in FIG. 17 or any other shape, or an area of the second electrode portions or a gap width between the strong plasma generation spaces 101 may be changed at the central and peripheral portions of the wafer as shown in FIG. 16.

In addition, a rotary shaft rotating around the vertical axis is installed at a central portion of the bottom of the mounting table 2 supporting the wafer, and the film formation is performed while the wafer on the mounting table 2 rotates, such that the in-plane uniformity of the film thickness in the circumferential direction may be more improved. Meanwhile, in the circular disc-shaped wafer, since a length in the circumferential direction at the central portion is different from that at the outer peripheral portion, for example, as shown in FIG. 12, if the wafer rotate under the electrode portions 41f having the same size and arranged checkerwise, the number of electrode portions 41f the wafer passes through is different between the central portion and the outer peripheral portion while the wafer makes one rotation. As a result, since the outer peripheral portion of the wafer is exposed to plasma concentrated portions (for example, regions under the strong plasma generation spaces 101) more frequently than the inner peripheral portion, it is apprehended that the non-uniformity of the film forming rate may be increased in the diameter direction.

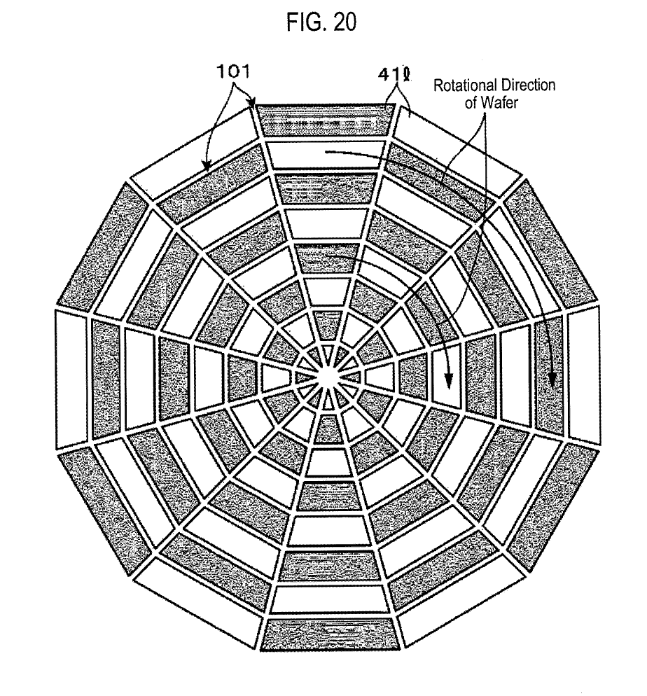

Therefore, if the wafer is rotated, as shown in FIG. 20, electrode portions 411 may be installed. In this case, the electrode portions 411 are divided from each other by the strong plasma generation spaces 101 extending along the circumferential direction of the wafer and the strong plasma generation spaces 101 extending along the direction crossing the circumferential direction, i.e., along the diameter direction of the wafer. With the electrode portions 411 divided as above, since the number of electrode portions 411 disposed over the central portion of the wafer is the same as the number of electrode portions 411 disposed over the outer peripheral portion, the wafer passes through the same number of electrode portions 411 and the same number of strong plasma generation spaces 101 extending in the diameter direction while the wafer makes one rotation. Thus, it is possible to provide the uniformity of the film forming rate in the diameter direction.

Further, as a method of adjusting the intensity of the plasma generated in the strong plasma generation spaces 101, a phase difference of the high frequency powers respectively applied from the first and second power source parts 61 and 62 may be adjusted to be smaller than 180 degrees, for example, 30 degrees or more to be less than 180 degrees, thereby decreasing the plasma intensity in comparison with the case in which the phases are inverted with respect to each other (a phase difference is 180 degrees).

Also, the high frequency power applied to the electrode portions 41 is not limited to an example of 13.56 MHz, and other high frequency power of other frequencies such as 100 MHz may be applied.

Furthermore, although it has been described as an example that in the film forming device 1 shown in FIG. 1, the reaction gas in the weak plasma generation space 102 is exhausted to the outside through the exhaust holes 431 formed in the bottom surfaces of the electrode portions 41, the exhaust channels 43 are not limited to the case in which they are formed in the electrode portions 41. For example, if the good film quality is obtained even though the exhaust is performed using the exhaust pipe 13 shown in FIG. 1, the use of the exhaust pipe 13 as an exhaust unit is not denied.

The present disclosure is also not limited to the case in which the Si film is formed from H₂ and SiH₄. For example, using H₂ as the first reaction gas and a silicon compound gas, for example, SiH₂Cl₂, other than SiH₄ as the second reaction gas, a microcrystalline Si film may be formed according to the present disclosure.

### Example

### Experiment 1

The film forming device 1 according to the present disclosure in which the phases of the high frequency powers are inverted with respect to each other and the high frequency powers are applied to the adjacent electrode portions 41 and a film forming device in which one side set of the adjacent electrode portions 41 is grounded were compared in terms of plasma intensity in the weak plasma generation space 102 and film forming rate distribution of the μc-Si film.

### A. Experimental Conditions

### Example 1

In the film forming device 1 shown in FIG. 1, the distance w between the electrode portions 41 was set to w=5 mm, the distance h between the bottom surface of the electrode portions 41 and the substrate S was set to h=20 mm, a high frequency power of 13.56 MHz and 400 W was applied from the first power source part 61, a high frequency power of 13.56 MHz and 600 W, the phase of which is delayed 180 degrees with respect to the high frequency power applied from the first power source part 61, was applied from the second power source part 62, and then, the interior of the process vessel 10 was photographed by a CCD camera with a band-pass filter to measure the plasma emission intensity. In addition, 1000 sccm of H₂ was supplied from the H₂ supply channels 32, 10 sccm of SiH₄ was supplied from the SiH₄ supply channels 42, and then, an in-plane distribution of film forming rate of a μc-Si film was measured. The internal pressure of the process vessel 10 was set to 900 Pa.

### Comparative Example 1

An emission intensity and an in-plane distribution of the film forming rate of a μc-Si film were measured under the same conditions as Example 1 except that a power of 500 W is applied from the first power source part 61 and the electrode portions 41 connected to the second power source part 62 in Example 1 was grounded.

### B. Experimental Results

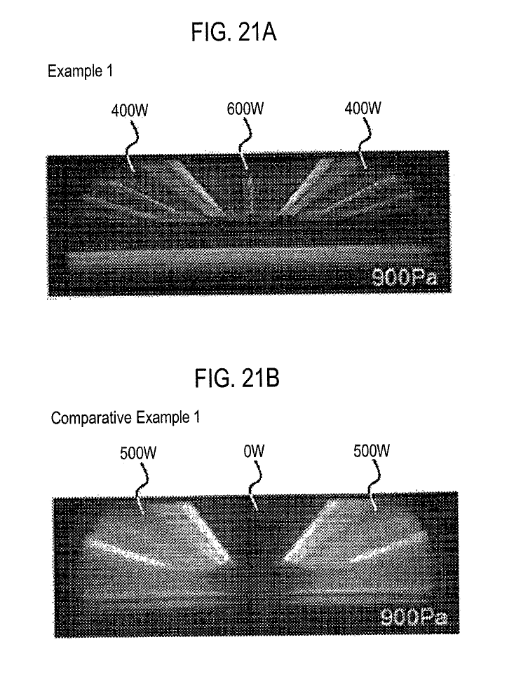

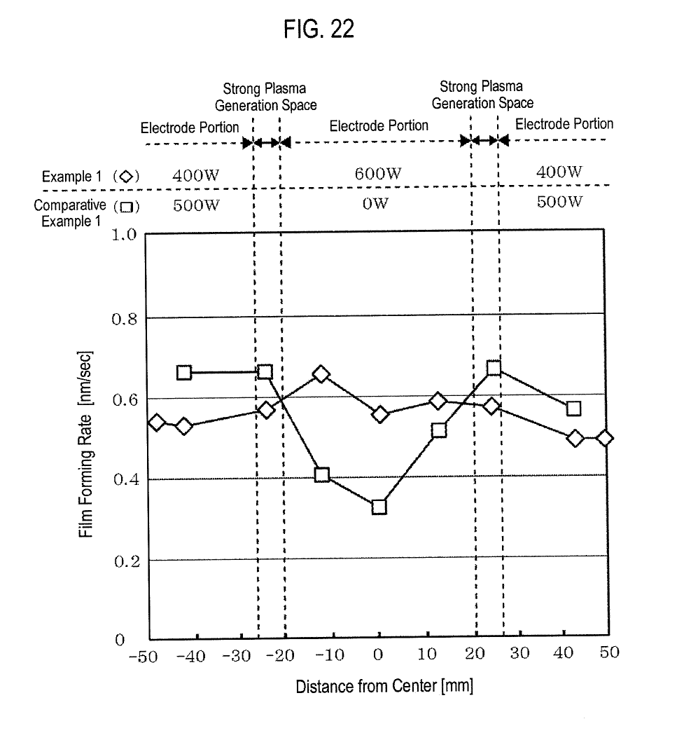

A photograph of an emission intensity measurement result according to Example 1 is shown in FIG. 21A, and a measurement result according to Comparative Example 1 is shown in FIG. 21B. In addition, in-plane distributions of film forming rate of μc-Si films according to Example 1 and Comparative Example 1 are shown in FIG. 22. The transverse axis of FIG. 22 represents a distance in the transverse direction from the center of the electrode portions 41 connected to the second power source part 62 or grounded, and the vertical axis represents a film forming rate [nm/second] of a μc-Si film at that point. In FIG. 22, a result of Example 1 is plotted as a rhombus, and a result of Comparative Example 1 is plotted as a square.

Comparing FIGS. 21A and 21B, FIG. 21A according to Example 1 shows that the emission intensities under the electrode portions 41 adjacently arranged have the same level, whereas Comparative Example 1 clearly shows that the regions under the electrode portions 41 connected to the first power source part 61 are bright and the region under the grounded electrode portion 41 is dark.

Such a difference in emission intensity is also reflected on the film forming rate distribution of the μc-Si film. As shown in FIG. 22, a film forming rate of Example 1 is relatively uniform between the respective electrode portions 41, whereas a film forming rate of Comparative Example 1 is clearly low in the region in which the grounded electrode portion 41 is disposed. This may be construed as the result that weak plasma is uniformly generated between the respective electrode portions 41 and the substrate S to promote the reaction of H radicals and SiH4 in Example 1, whereas since plasma is hardly generated under the grounded electrode portion 41 in Comparative Example 1, the reaction of H radicals and SiH₄ under the grounded electrode portion 41 is mainly dominated only by the heating of the substrate S.

### Experiment 2

An electron density distribution in the weak plasma generation space 102 was measured when the inclined surface portions 46 are provided in the electrode portions 41 and when the inclined surface portions 46 are not provided therein.

### A. Experimental Conditions

### Example 2-1

In the example shown in FIG. 6, when the distance w between the electrode portions 41 was set to w=10 mm, the distance h between the bottom surface of the electrode portions 41 and the substrate S was set to h=20 mm, a high frequency power of 13.56 MHz and 400 W was applied from the first power source part 61, and a high frequency power of 13.56 MHz and 600 W, the phase of which is delayed 180 degrees with respect to the high frequency power applied from the first power source part 61, was applied from the second power source part 62, and then an electron density distribution in the strong plasma generation spaces 101 and the weak plasma generation space 102 was measured by a plasma fluid model. The plasma fluid model is described in M. J. Kushner: J. Phys. D42, 194013(2009). In addition, the internal pressure of the process vessel 10 was set to 900 Pa.

### Example 2-2

The experiment was performed under the same conditions as Example 2-1 except that the bottom surfaces of the electrode portions 41 are provided with the inclined surface portions 46 in the same manner as the example shown in FIG. 7, h₁=20 mm, and h₂=10 mm.

### B. Experimental Results

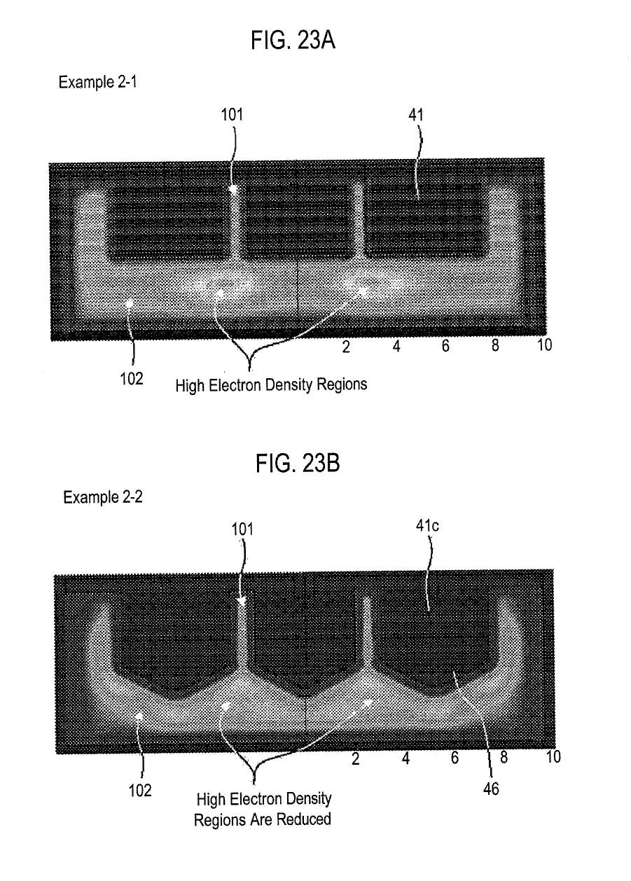

An experimental result of Example 2-1 is shown in FIG. 23A, and an experimental result of Example 2-2 is shown in FIG. 23B.

According to the experimental result of Example 2-1 shown in FIG. 23A, high electron density regions were found under the openings of the strong plasma generation spaces 101. Contrarily, in Example 2-2 shown in FIG. 23B, as the bottom surfaces of the electrode portions 41 c are provided with the inclined surface portions 46, each of which is inclined from both the sidewall surfaces of each electrode portion 41c toward the central portion thereof, the high electron density regions observed in Example 2-1 are considerably reduced and plasma is uniformly generated throughout the weak plasma generation space 102. This may be because as the coupling of the leading end of the inclined surface portion 46 and the substrate S is intensified, the concentration of electron density at the outlets of the strong plasma generation spaces 101 is relieved.

### Experiment 3

As shown in FIG. 5, when the frequency signal generator 63 is connected to the first and second power source parts 61 and 62 through the first and second signal lines 611 and 621, respectively, and the length of the second signal line 621 is changed, waveforms of high frequency powers output from the first and second power source parts 61 and 62 were measured by an oscilloscope.

### A. Experimental Conditions

### Example 3-1

The length of the first signal line 611 from the frequency signal generator 63 to the first power source part 61 was set to 1 m, and the length of the second signal line 621 from the frequency signal generator 63 to the second power source part 62 was set to 8.4 m.

### Example 3-2

The others except that the length of the second signal line 621 from the frequency signal generator 63 to the second power source part 62 was set to 2.85 m were the same as Example 3-1.

### Example 3-3

The others except that the length of the second signal line 621 from the frequency signal generator 63 to the second power source part 62 was set to 4.7 m were the same as Example 3-1.

### B. Experimental Results

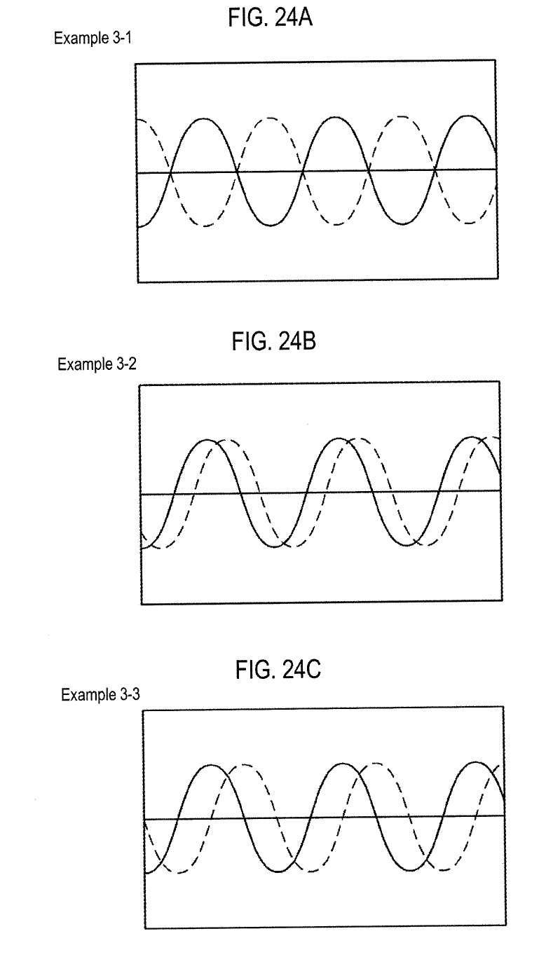

Waveform measurement results of high frequency powers in Examples 3-1 to 3-3 are shown in FIGS. 24A to 24C, respectively. In the respective diagrams, the waveform of the high frequency power output from the first power source part 61 is represented by a solid line, and the waveform of the high frequency power output from the second power source part 62 is represented by a broken line.

According to Example 3-1 shown in FIG. 24A, as a difference in length between the first and second signal lines 611 and 621 is set to 7.4 m, the high frequency powers respectively output from the first and second power source parts 61 and 62 could be made to have a phase difference of 180 degrees (phase inversion). Further, in the cases of Example 3-2 shown in FIG. 24B and Example 3-3 shown in FIG. 24C, as differences in length between the first and second signal lines 611 and 621 are set to 1.85 m and 3.7 m, phase differences of the high frequency powers could be changed to 45 degrees and 90 degrees, respectively. From these results, as shown in FIG. 5, when the high frequency powers are synchronized with the frequency signal input from the frequency signal generator 63 and output from the first and second power source parts 61 and 62, it was confirmed that a phase difference between the high frequency powers applied to the adjacent electrode portions 41 could be adjusted by setting the first and second signal lines 611 and 621 to have different lengths.

### Experiment 4

When the internal pressure of the process vessel 10 is changed, an intensity of electric field formed on the surface of the substrate S was measured.

### A. Experimental Conditions

### Example 4

Under the same conditions as Example 2-1, while the internal pressure of the process vessel 10 was changed from 200 to 1000 Pa by 200 Pa, a change in electric field intensity according to a change in the internal pressure was measured.

### Comparative Example 4-1

The experiment was performed under the same conditions as Example 4 except that powers having the same phase (a phase difference of 0 degree) are applied to the adjacent electrode portions 41.

### Comparative Example 4-2

A change in electric field intensity according to a change in the internal pressure was measured when the substrate S was mounted on a flat parallel plate-shaped lower electrode with a gap of 5 mm between the electrodes 41 and a high frequency power of 13.56 MHz and 500 W was applied.

### B. Experimental Results

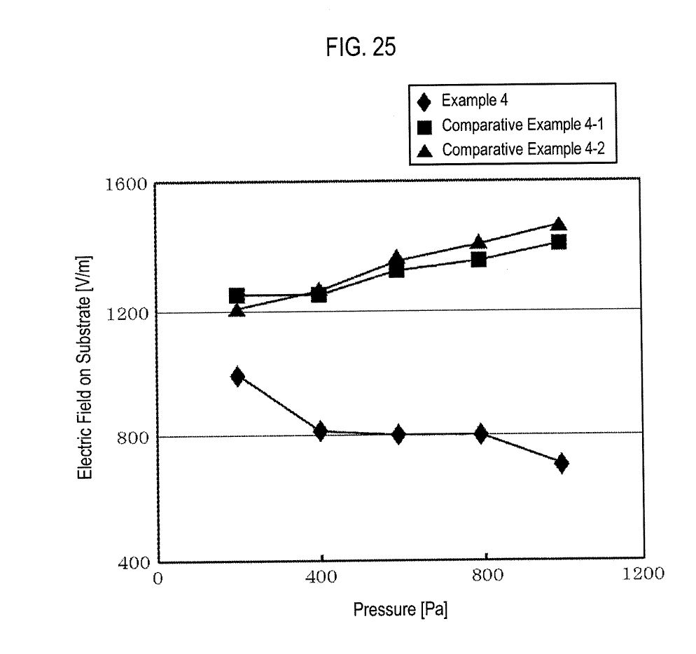

Experimental results of Example 4 and Comparative Examples 4-1 and 4-2 are shown in FIG. 25. The transverse axis of the diagram represents an internal pressure (Pa) of the process vessel 10, and the vertical axis represents an intensity (V/m) of an electric field on the substrate S. In addition, a result of Example 4 is plotted as a rhombus, and results of Comparative Examples 4-1 and 4-2 are plotted as a square and a triangle, respectively.

According to the results shown in FIG. 25, Example 4 in which the phases of the high frequency powers applied to the adjacent electrode portions 41 are inverted with respect to each other (different from each other by 180 degrees) had a smaller intensity of the electric field on the substrate S than Comparative Examples 2-1 and 2-2 at any pressure. Therefore, as compared with the case in which the phases of the high frequency powers applied to the adjacent electrode portions 41 are the same or the conventional flat parallel shaped electrode is used, the weak plasma generation space 102 in which an electric field intensity is weak can be easily formed, and SiH₃ can be supplied to the surface of the substrate S at a high concentration while suppressing the generation of unnecessary active species.

### Experiment 5

When a supply ratio of H₂ gas to SiH₄ gas (H₂/SiH₄) was changed, a film forming rate and a degree of crystallization of the formed μc-Si film were measured.

### A. Experimental Conditions

### Example 5

While changing an H₂/SiH₄ value to 25 (H₂: 1000 sccm, SiH₄: 40 sccm), 33 (H₂: 1000 sccm, SiH₄: 30 sccm), 50 (H₂: 1000 sccm, SiH₄: 20 sccm) and 100 (H₂: 1000 sccm, SiH₄: 10 sccm) under the same conditions as Example 2-1, a film forming rate and a degree of crystallization (peak intensity corresponding to mass % of a crystallized portion (Xc)) of the μc-Si film were measured by Raman spectroscopy.

### Comparative Example 5

The experiment was performed under the same conditions as Example 5 except that powers having the same phase (a phase difference of 0 degree) are applied to the adjacent electrode portions 41.

### B. Experimental Results

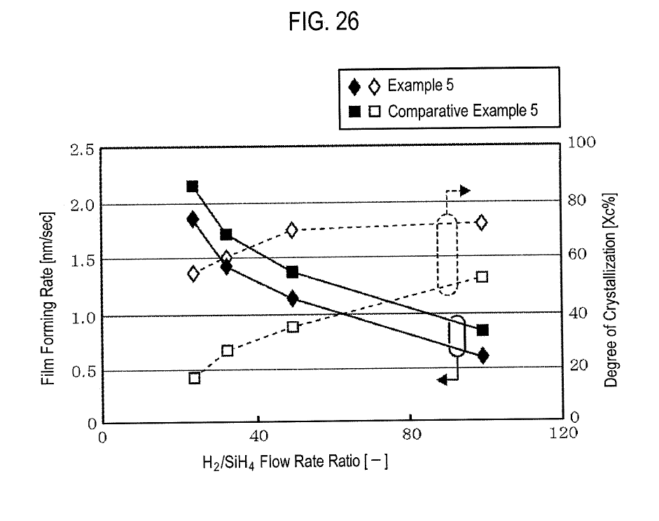

Experimental results of Example 5 and Comparative Example 5 are shown in FIG. 26. The transverse axis of the diagram represents an H₂/SiH₄ value, the left vertical axis represents a film forming rate (mm/sec), and the right vertical axis represents a degree of crystallization (Xc%). In addition, a result of Example 5 is plotted as a rhombus, and a result of Comparative Example 5 is plotted as a square. A black colored plot represents a film forming rate, and a white colored plot represents a degree of crystallization (peak intensity % of a crystallized portion).

According to the results in FIG. 26, when the H₂/SiH₄ value is changed, the film forming rate of Example 5 is smaller than that of Comparative Example 5 at any H₂/SiH₄ value. As can be seen from the results of Experiment 4, this may be because if the phases of the high frequency powers applied to the adjacent electrode portions 41 are inverted with respect to each other, as compared with the same phases, an electric field intensity of the surface of the substrate S is small and the amount of active species generated in the weak plasma generation space 102 is small. In the meantime, it can be seen that if the H₂/SiH₄ value is decreased and the relative supply amount of the SiH₄ gas is increased in both Example 5 and Comparative Example 5, the film forming rate is increased.

In addition, regarding a degree of crystallization, when the H₂/SiH₄ value is changed, Example 5 has a larger amount of crystal contained in the μc-Si film than Comparative Example 5 at any H₂/SiH₄ value, and thus, the μc-Si film having a high degree of crystallization and a good film quality may be obtained in Example 5. Further, if the H₂/SiH₄ value is increased and the relative supply amount of the H₂ gas is increased in both Example 5 and Comparative Example 5, the degree of crystallization tends to be improved. Therefore, by setting the H₂/SiH₄ value as a process parameter, it is possible to form a film by selecting conditions where a film forming rate is increased while satisfying the required film quality.

According to the present disclosure, the high frequency powers having different phases are respectively applied to one side set and the other side set of the plate-shaped electrode portions disposed to be spaced apart from each other. Further, plasma is generated in the strong plasma generation spaces interposed between the electrode portions, and another plasma having a weaker emission intensity than the plasma generated in the strong plasma generation spaces is generated in the gaps between the substrate on which a film is formed and the respective electrode portions. In addition, active species of the first reaction gas is generated in the strong plasma generation spaces, and the active species generated in the strong plasma generation spaces react with the second reaction gas in the weak plasma generation space, thereby enabling a thin film having less defects to be uniformly formed on the surface of the substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming device of forming a thin film on a substrate by reacting a plurality of reaction gases in a process vessel, the device comprising:
a mounting table installed in the process vessel to be mounted with the substrate;
a plurality of plate-shaped electrode portions disposed, over the substrate mounted on the mounting table, to be spaced apart from each other in a transverse direction with each of the electrode portions vertically oriented, so that strong plasma generation spaces are defined between the electrode portions, the electrode portions being configured to define a weak plasma generation space in a gap between lower ends of the electrode portions and the substrate, the weak plasma generation space being configured to generate plasma having a weaker emission intensity than plasma generated in the strong plasma generation spaces;
a first reaction gas supply unit configured to supply a first reaction gas into the strong plasma generation spaces;
a second reaction gas supply unit configured to supply a second reaction gas into regions under the strong plasma generation spaces or into the weak plasma generation space, the second reaction gas reacting with active species of the first reaction gas to form the thin film on the substrate;
an exhaust unit configured to exhaust the reaction gases from the weak plasma generation space; and
first and second high frequency power source parts configured to respectively apply high frequency powers having different phases to one side set and the other side set of the electrode portions which are adjacent with the strong plasma generation spaces interposed therebetween,
wherein a distance between the adjacent electrode portions with the strong plasma generation spaces interposed therebetween is in a range of 2 mm or more to 20 mm or less, and a distance between the substrate on the mounting table and the electrode portions is in a range of 5 mm or more to 100 mm or less.

2. The film forming device of claim 1, wherein a bottom surface of each of the plate-shaped electrode portions is provided with an inclined surface portion, which is inclined from both sidewall surfaces of the electrode portion toward a central portion thereof.

3. The film forming device of claim 1, wherein the mounting table includes a moving mechanism configured to reciprocate the substrate mounted on the mounting table along a direction in which the plurality of electrode portions are arranged.

4. The film forming device of claim 1, wherein a plane shape of the electrode portions is formed so that the distance between the adjacent electrode portions with the strong plasma generation spaces interposed therebetween is large in a high film forming rate region and small in a low film forming rate region.

5. The film forming device of claim 1, wherein a plurality of cutaway portions are arranged to be spaced apart from each other in a sidewall surface of the electrode portions, the plurality of cutaway portions being formed by cutting off the sidewall surface of the adjacent electrode portions with the strong plasma generation spaces interposed therebetween.

6. The film forming device of claim 1, wherein each of the plate-shaped electrode portions is divided so that the strong plasma generation spaces are formed in an intersecting direction across the strong plasma generation spaces formed between the plate-shaped electrode portions, and the first and second high frequency power source parts respectively apply high frequency powers having different phases to the adjacent electrode portions with the strong plasma generation spaces extending in the intersecting direction interposed therebetween.

7. The film forming device of claim 1, wherein the exhaust unit includes:
an exhaust channel formed in each of the electrode portions; and
a plurality of exhaust holes provided in a bottom surface of each of the electrode portions, so that the reaction gases in the weak plasma generation space are exhausted through the exhaust channel.

8. The film forming device of claim 1, wherein the first reaction gas includes hydrogen gas, and the second reaction gas includes silicon compound gas.

9. The film forming device of claim 1, wherein an internal pressure of the process vessel is 100 Pa or more to 2000 Pa or less.

10. A film forming device of forming a thin film on a substrate by reacting a plurality of reaction gases in a process vessel, the device comprising:
a mounting table installed in the process vessel to be mounted with the substrate;
a plate-shape first electrode portion configured to cover an upper side of a plane surface of the substrate, a plurality of openings being formed in the first electrode portion to be spaced apart from each other;
a plurality of second electrode portions respectively disposed inside the openings with gaps formed between inside surfaces of the openings and the second electrode portions so that strong plasma generation spaces are defined by the gaps, the first and second electrode portions being configured to define a weak plasma generation space in a gap between lower ends of the first and second electrode portions and the substrate, the weak plasma generation space being configured to generate plasma having a weaker emission intensity than plasma generated in the strong plasma generation spaces;
a first reaction gas supply unit configured to supply a first reaction gas into the strong plasma generation spaces;
a second reaction gas supply unit configured to supply a second reaction gas into regions under the strong plasma generation spaces or into the weak plasma generation space, the second reaction gas reacting with active species of the first reaction gas to form the thin film on the substrate;
an exhaust unit configured to exhaust the reaction gases from the weak plasma generation space; and
first and second high frequency power source parts configured to respectively apply high frequency powers having different phases to the first and second electrode portions,
wherein the gaps defining the strong plasma generation spaces are in a range of 2 mm or more to 20 mm or less, and the gap defining the weak plasma generation space is in a range of 5 mm or more to 100 mm or less.

11. The film forming device of claim 10, wherein the mounting table includes a moving mechanism configured to reciprocate the substrate mounted on the mounting table in a transverse direction.

12. The film forming device of claim 10, wherein the exhaust unit includes:
an exhaust channel installed above the first and second electrode portions; and
a plurality of exhaust holes provided in bottom surfaces of the first and second electrode portions, so that the reaction gases in the weak plasma generation space are exhausted through the exhaust channel.

13. The film forming device of claim 10, wherein the first reaction gas includes hydrogen gas, and the second reaction gas includes silicon compound gas.

14. The film forming device of claim 10, wherein an internal pressure of the process vessel is 100 Pa or more to 2000 Pa or less.
